(19) United States
(12) Patent Application Publication
(10) Pub. No.: US 2004/0241948 A1
(43) Pub. Date: Dec. 2, 2004

(54) Method of fabricating stacked gate dielectric layer

(76) Inventors: Chun-Feng Nieh, Hsinchu (TW); Hsien-Wei Chen, Tainan (TW); Fung-Hsu Cheng, Taoyuan (TW); Zhen-Long Chen, Tainan (TW); Shun-Tien Chou, Taichung (TW)

Correspondence Address: BIRCH STEWART KOLASCH & BIRCH, PO BOX 747, FALLS CHURCH, VA, 22040-0747, US

(21) Appl. No.: 10/446,871

(22) Filed: May 29, 2003

(51) Int. Cl. H01L 21/336

(52) U.S. Cl. 438/287; 438/775; 438/954

(57) ABSTRACT

A method of fabricating a stacked gate dielectric layer. First, a semiconductor substrate having a native oxide thereon is provided. Next, a first gas containing hydrogen is introduced on the semiconductor substrate. A nitride is deposited on the native oxide. A second gas containing nitrous oxide is introduced on the semiconductor substrate. A third gas containing nitrogen oxide is introduced on the semiconductor substrate. Finally, an annealing treatment is performed.

### BACKGROUND OF THE INVENTION

1. Field of the Invention

The present invention relates to a method of fabricating a stacked gate dielectric layer, and in particular to a method of fabricating an ONO (oxide/nitride/oxide) stacked gate dielectric layer having thin pad nitride.

2. Description of the Related Art

Recent advances in the field of metal-oxide-semiconductor (MOS) technology have included scaling down of the thickness of the gate dielectric layer, creating a number of problems. For example, as the overall size becomes “ultra-thin”, e.g., less than 75 nm, Si/SiO₂ interface characteristics play dominant roles in the quality of the gate dielectric layer. The ultra-thin gate dielectric layer suffers from excessive tunneling current problems as they approach the tunneling limit. On such thin gate dielectrics, suppression of boron diffusion from the poly gate into channel regions is also a serious concern. These problems have severely hampered the ability to fabricate integrated circuit utilizing “ultra-thin” designs.

To address such problems, the art has sought to provide a reliable, high quality gate dielectric layer having desired properties of low defect density and high breakdown field strength, allowing sustained quality during advanced processing. Oxide/nitride (ON) and oxide/nitride/oxide (ONO) structures having excellent behavior are provided, however, it is difficult to reduce the thickness of such structures. The effective oxide thickness (EOT) of the ON or ONO gate dielectric layer is difficult to control.

### SUMMARY OF THE INVENTION

Accordingly, an object of the present invention is to provide a method of fabricating an ONO stacked gate dielectric layer with high dielectric constant to prevent boron ion penetration from the gate layer.

It is another object of the present invention to provide a method of fabricating an ONO stacked gate dielectric layer to reduce surface defects.

It is a further object of the present invention to provide a method of fabricating an ONO stacked gate dielectric layer to form a thin nitride pad between the semiconductor substrate and the ONO stacked gate dielectric layer.

Key feature of the present invention is use of a first gas containing hydrogen to reduce the thickness of the native oxide serving as a lower oxide of the ONO structure.

Another key feature of the present invention is use of a second gas containing nitrous oxide to form a thermal oxide serving as an upper oxide of the ONO structure and to eliminate the residual nitrogen between the semiconductor substrate and the native oxide.

Still another key feature of the present invention is use of a third gas containing nitrogen oxide to form a thin nitride pad, which can prevent boron ion penetration from the gate layer, between the semiconductor substrate and the native oxide.

To achieve these and other advantages, the invention provides a method of fabricating a stacked gate dielectric layer. First, a semiconductor substrate having a native oxide thereon is provided. Next, a first gas containing hydrogen is introduced on the semiconductor substrate. A nitride is deposited on the native oxide. A second gas containing nitrous oxide is introduced on the semiconductor substrate. A third gas containing nitrogen oxide is introduced on the semiconductor substrate. Finally, an annealing treatment is performed.

The native oxide with thickness of about 8˜10 Å is formed by chemical cleaning. After introducing the first gas containing hydrogen, the thickness of the native oxide is reduced to about 4˜5 Å.

The pressure of the first gas containing hydrogen, introduced for about 20˜40 seconds, is about 800˜700 torr.

The nitride is deposited by chemical vapor deposition (CVD) at about 700˜800° C. for about 6˜10 seconds, creating thickness of the nitride of about 2˜9 Å.

According to the present invention, the second gas containing nitrous oxide is introduced at about 900˜1100° C. for about 6˜10 seconds.

According to the present invention, the third gas containing nitrogen oxide is introduced at about 800˜1000° C. for about 10˜20 seconds.

According to the present invention, the annealing treatment is performed at about 900˜1100° C. for about 30˜60 seconds in a nitrogen atmosphere.

### BRIEF DESCRIPTION OF THE DRAWINGS

The present invention can be more fully understood by reading the subsequent detailed description and examples with references made to the accompanying drawings, wherein:

FIG. 1 is a flowchart of the method according to a preferred embodiment of the present invention;

FIGS. 2A through 2J are cross-sections showing the method according to a preferred embodiment of the present invention.

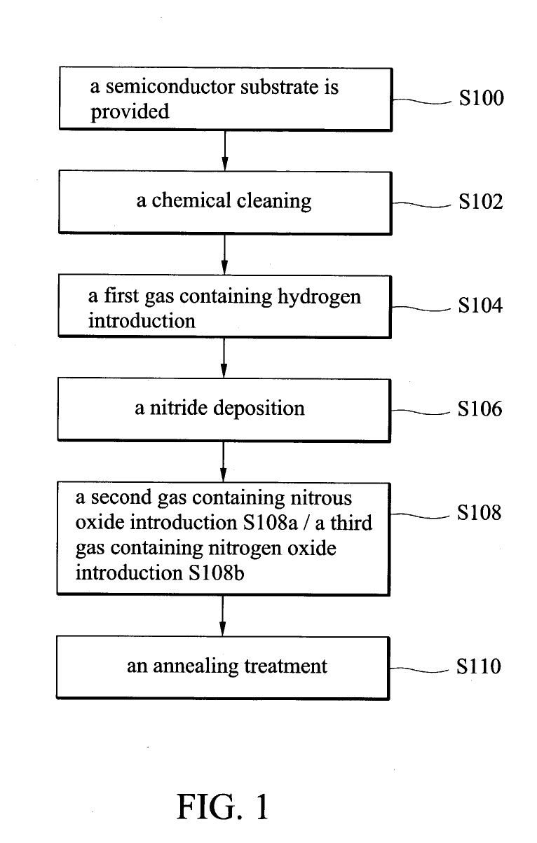

### DETAILED DESCRIPTION OF THE INVENTION

A preferred embodiment of the present invention is now described with reference to the figures.

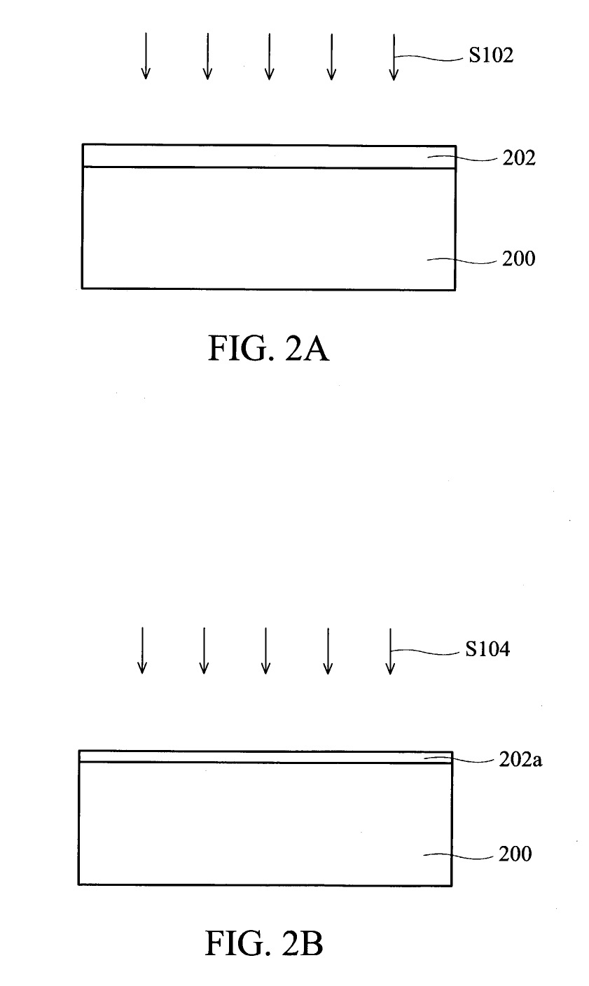

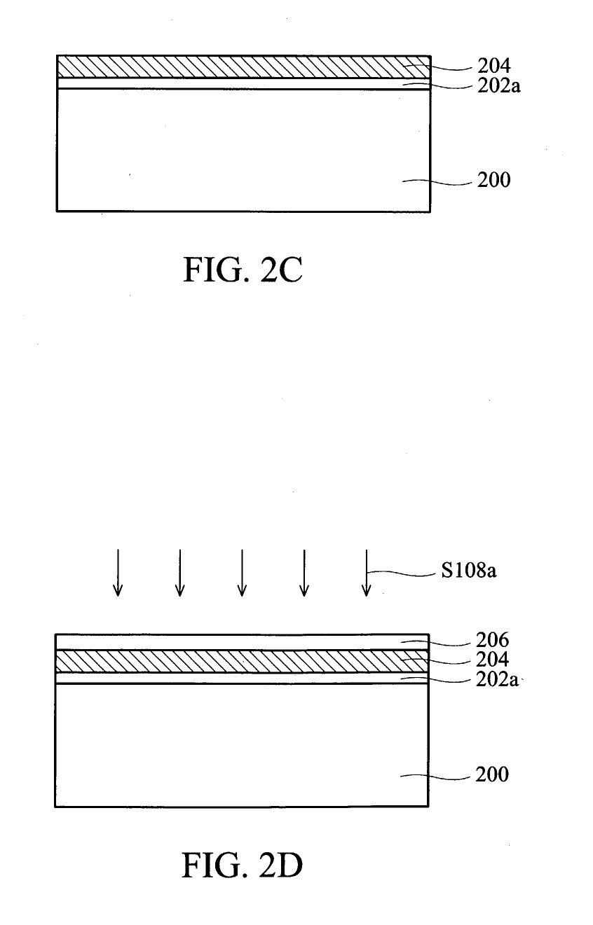

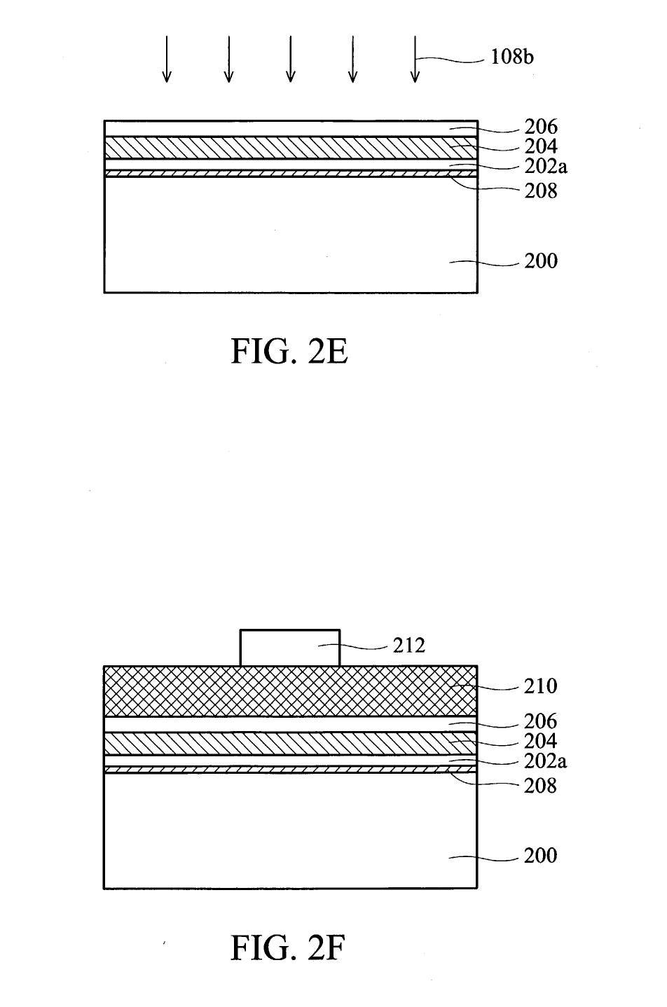

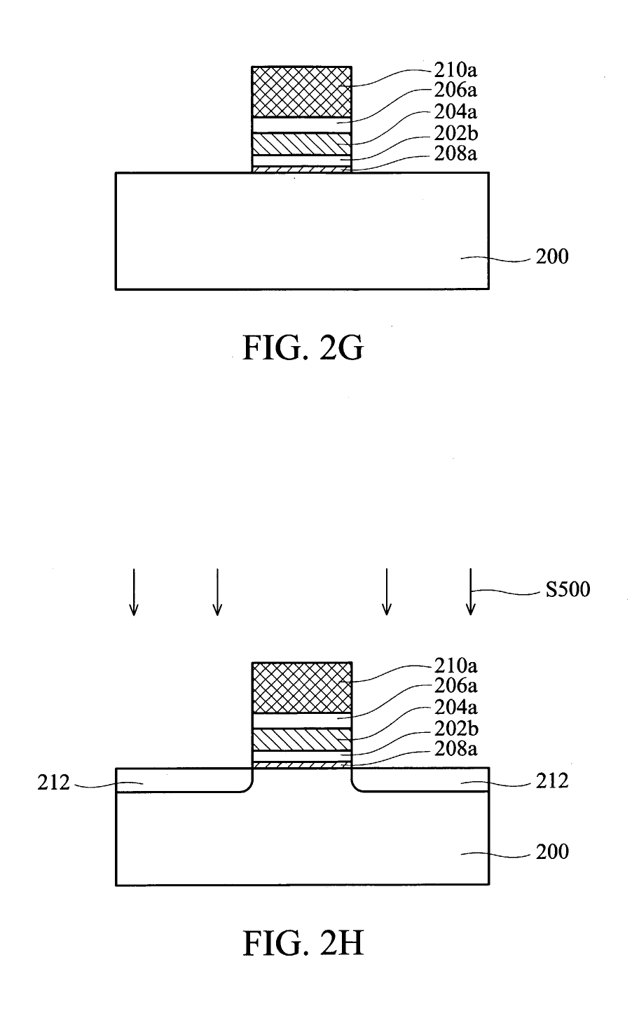

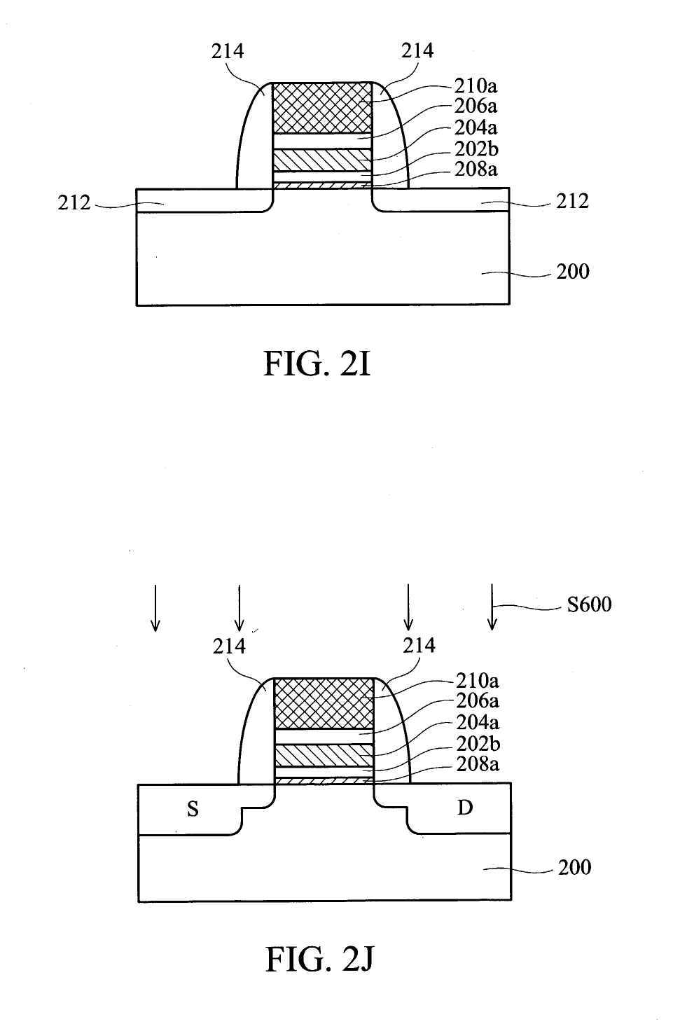

First, in step S100, a semiconductor substrate 200, such as silicon, is provided, as shown in FIG. 2A. The semiconductor substrate 200 is preferably treated by chemical cleaning to form a native oxide 202 thereon.

Next, in step S104, a first gas containing hydrogen is introduced on the semiconductor substrate 200 to reduce the thickness of the native oxide, as shown in FIG. 2B. After introducing the first gas containing hydrogen, the thickness of the native oxide 202a is reduced to about 4˜5 Å. The pressure of the first gas containing hydrogen introduced for about 20˜40 seconds, is about 800˜700 torr.

In S106, a nitride 204 is preferably deposited on the native oxide 202a by chemical vapor deposition (CVD), such as low pressure chemical vapor deposition (LPCVD), at about 700˜800° C. for about 6˜10 seconds, as shown in FIG. 2C. The thickness of the nitride 204 is about 2˜9 Å, and the nitride 204 comprises silicon nitride.

In S108a, a second gas containing nitrous oxide is introduced on the semiconductor substrate 200. The second gas containing nitrous oxide is preferably introduced at about 900˜1100° C. for about 6˜10 seconds. A thermal oxide 206 is formed on the nitride 204 after introducing the second gas containing nitrous oxide, as shown in FIG. 2C. As well, residual nitrogen between the semiconductor substrate 200 and the native oxide 202a is eliminated.

In S108b, a third gas containing nitrogen oxide is introduced on the semiconductor substrate 200. The third gas containing nitrogen oxide is preferably introduced at about 800˜1000° C. for about 10˜20 seconds. Thus, a thin pad nitride 208, which can prevent boron ion penetration from the gate layer following formed on the gate dielectric layer, is formed between the native oxide 202a and the semiconductor substrate 200, as shown in FIG. 2E. The material of the thin pad nitride 208 comprises SiOₓN_{y}.

Finally, in S110, an annealing treatment is preferably performed at about 900˜1100° C. for about 30˜60 seconds in a nitrogen atmosphere.

Therefore, an ONO stacked gate dielectric layer comprising the native oxide 202a, the nitride 204, and the thermal oxide 206 is obtained. As well, a thin pad nitride 208 formed between the semiconductor substrate 200 and the ONO stacked gate dielectric layer is also obtained.

According to the present invention, the first gas containing hydrogen introduction S104, the nitride deposition S106, the second gas containing nitrous oxide introduction S108a, the third gas containing nitrogen oxide introduction S108b, and the annealing treatment S110 are preferably performed in-situ.

The ONO stacked gate dielectric layer is suitable for use in a metal oxide semiconductor (MOS). In order to illustrate and clarify the application of the ONO stacked gate dielectric layer according to the present invention, the MOS formation process is explained as follows.

In FIG. 2F, a gate layer 210, such as poly-silicon, is formed on the thermal oxide 206. The gate layer 210 is preferably doped with boron ions to enhance threshold voltage. A patterned photoresist layer 212 is preferably formed by spin coating and photolithography. The gate layer 210, the thermal oxide 206, the nitride 204, and native oxide 202a are subsequently etched using the patterned photoresist layer 212 as a shield until parts of the semiconductor substrate 200 are exposed, as shown in FIG. 2G.

In FIG. 2H, a first ion implantation S500 is performed on the semiconductor substrate 200 using the patterned gate layer 210a, the patterned thermal oxide 206a, the patterned nitride 204a, the patterned native oxide 202b, and the patterned thin pad nitride 208a as a shield to form lightly doped drain regions in the semiconductor substrate 200 beside the ONO stacked gate dielectric layer.

In FIG. 2I, spacers 214 comprising nitride are preferably formed on the side walls of the ONO stacked gate dielectric layer by deposition and etching.

In FIG. 2J, a second ion implantation S600 is performed using the ONO stacked gate dielectric layer and the spacers 214 as shields to form a source/drain region S/D in the semiconductor substrate 200 beside the ONO stacked gate dielectric layer. Thus, the metal oxide semiconductor (MOS) is obtained.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A method of fabricating a stacked gate dielectric layer, comprising:
providing a semiconductor substrate having a native oxide thereon;
introducing a first gas containing hydrogen on the semiconductor substrate;
depositing a nitride on the native oxide;
introducing a second gas containing nitrous oxide on the semiconductor substrate;
introducing a third gas containing nitrogen oxide on the semiconductor substrate; and
performing an annealing treatment.

2. The method as claimed in claim 1, wherein the native oxide is formed by chemical cleaning.

3. The method as claimed in claim 1, wherein the thickness of the native oxide is about 8˜10 Å.

4. The method as claimed in claim 3, wherein the thickness of the native oxide is about 4˜5 Å after introducing the first gas containing hydrogen.

5. The method as claimed in claim 1, wherein the pressure of the first gas containing hydrogen is about 800˜700 torr.

6. The method as claimed in claim 1, wherein the first gas containing hydrogen is introduced for about 20˜30 seconds.

7. The method as claimed in claim 1, wherein the nitride is deposited by chemical vapor deposition (CVD).

8. The method as claimed in claim 1, wherein the nitride is deposited at about 700˜800° C.

9. The method as claimed in claim 1, wherein the nitride is deposited for about 6˜10 seconds.

10. The method as claimed in claim 1, wherein the thickness of the nitride is about 2˜9 Å.

11. The method as claimed in claim 1, wherein the second gas containing nitrous oxide is introduced at about 900˜1100° C.

12. The method as claimed in claim 1, wherein the second gas containing nitrous oxide is introduced for about 6˜10 seconds.

13. The method as claimed in claim 1, wherein the third gas containing nitrogen oxide is introduced at about 800˜1000° C.

14. The method as claimed in claim 1, wherein the third gas containing nitrogen oxide is introduced for about 10˜20 seconds.

15. The method as claimed in claim 1, wherein a thermal oxide is formed on the nitride after introducing the second gas containing nitrous oxide.

16. The method as claimed in claim 1, wherein a thin pad nitride is formed between the native oxide and the semiconductor substrate.

17. The method as claimed in claim 1, wherein the annealing treatment is performed in a nitrogen atmosphere.

18. The method as claimed in claim 1, wherein the annealing treatment is performed at about 900˜1100° C.

19. The method as claimed in claim 1, wherein the annealing treatment is performed for about 30˜60 seconds.
